(19) United States
(12) Patent Application Publication
(10) Pub. No.: US 2025/0212444 A1
(43) Pub. Date: Jun. 26, 2025

(54) SEMICONDUCTOR DEVICE AND METHOD FOR MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Tsutomu KIYOSAWA, Himeji Hyogo (JP)

(21) Appl. No.: 19/073,625

(22) Filed: Mar. 7, 2025

Related U.S. Application Data
(63) Continuation of application No. PCT/JP2024/013862, filed on Apr. 3, 2024.

(30) Foreign Application Priority Data
Jul. 25, 2023 (JP) 2023-120397

(51) Int. Cl. H10D 30/01; H01L 21/66; H10D 62/60; H10D 62/832

(52) U.S. Cl. CPC H10D 30/0297; H01L 22/12; H10D 62/60; H10D 62/8325

(57) ABSTRACT

A method of an embodiment includes: forming, in a first region of an upper surface of a first-conductivity-type first silicon carbide layer, a second silicon carbide layer having a first-conductivity-type impurity concentration different from that of the first silicon carbide layer and having a first film thickness D2; forming a second-conductivity-type third silicon carbide layer having a film thickness D4 in a second region of the upper surface; forming, on the first silicon carbide layer, a fourth silicon carbide layer having a lower first-conductivity-type impurity concentration than the second silicon carbide layer and having a film thickness D1; measuring a second film thickness D3 of the second silicon carbide layer and the film thickness D1 of the fourth silicon carbide layer; and forming a trench penetrating the fourth silicon carbide layer to reach the third silicon carbide layer based on the film thickness D1, D2, D3, D4.

### CROSS-REFERENCE TO RELATED APPLICATION

This application is based upon and claims the benefit of priority from Japanese Patent Application No. 2023-120397, filed on Jul. 25, 2023, the entire contents of which are incorporated herein by reference.

Embodiments of the present invention relate to a semiconductor device and a method for manufacturing the same.

### BACKGROUND

SiC (silicon carbide) is expected as a material for next-generation semiconductor devices. Silicon carbide has a bandgap of about 3 times, a breakdown field strength of about 10 times, and a thermal conductivity of about 3 times that of Si (silicon). Therefore, by using SiC, it is possible to realize a semiconductor device that can operate at high temperature with low loss.

### BRIEF DESCRIPTION OF THE DRAWINGS

FIG. 1 is a schematic cross-sectional view of a semiconductor device according to a first embodiment;

FIGS. 2A and 2B are schematic diagrams showing an example of a location where a first region is arranged;

FIGS. 3A to 3F are schematic cross-sectional views showing steps of manufacturing the semiconductor device according to the first embodiment;

FIG. 4 is a schematic cross-sectional view of a semiconductor device according to a second embodiment;

FIGS. 5A to 5F are schematic cross-sectional views showing steps of manufacturing the semiconductor device according to the second embodiment;

FIG. 6 is a schematic cross-sectional view of a semiconductor device according to a third embodiment;

FIGS. 7A to 7F are schematic cross-sectional views showing steps of manufacturing the semiconductor device according to the third embodiment; and

FIG. 8 is a schematic cross-sectional view of a semiconductor device according to a fourth embodiment.

### DETAILED DESCRIPTION

A method for manufacturing a semiconductor device according to an embodiment includes: a step of forming, in a first region of an upper surface of a first-conductivity-type first silicon carbide layer, a second silicon carbide layer having a first-conductivity-type impurity concentration different from that of the first silicon carbide layer and having a first film thickness D2; a step of forming a second-conductivity-type third silicon carbide layer having a film thickness D4 in a second region of the upper surface; a step of forming, on the first silicon carbide layer, a fourth silicon carbide layer having a lower first-conductivity-type impurity concentration than the second silicon carbide layer and having a film thickness D1; a step of measuring a second film thickness D3 of the second silicon carbide layer and the film thickness D1 of the fourth silicon carbide layer in a direction from the first silicon carbide layer to the fourth silicon carbide layer after the fourth silicon carbide layer is formed; and a step of forming a trench having a predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer.

Hereinafter, embodiments of the invention will be described with reference to the diagrams. In addition, in the following description, the same members and the like are denoted by the same reference numerals, and the description of the members and the like once described will be omitted as appropriate.

In the following description, when the notations of n⁺, n, n⁻, p⁺, p, and p⁻ are used, these notations indicate the relative high and low of the impurity concentration in each conductivity type. That is, n⁺ indicates that the n-type impurity concentration is relatively higher than n, and n-indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentration can be measured by C-V measurement (capacitance measurement). In addition, the impurity concentration can be measured by, for example, SIMS (Secondary Ion Mass Spectrometry). In addition, the relative high and low of the impurity concentration can also be determined from, for example, the high and low of the carrier concentration obtained by SCM (Scanning Capacitance Microscopy). In addition, the distance such as the depth of an impurity region can be calculated by, for example, SIMS. In addition, the distance such as the width or depth of an impurity region can be calculated from, for example, an SCM image.

Hereinafter, the first conductivity type will be referred to as n-type, and the second conductivity type will be referred to as p-type.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

### First Embodiment

A method for manufacturing a semiconductor device according to the present embodiment includes: a step of forming, in a first region of an upper surface of a first-conductivity-type first silicon carbide layer, a second silicon carbide layer having a first-conductivity-type impurity concentration different from that of the first silicon carbide layer and having a first film thickness D2; a step of forming a second-conductivity-type third silicon carbide layer having a film thickness D4 in a second region of the upper surface; a step of forming, on the first silicon carbide layer, a fourth silicon carbide layer having a lower first-conductivity-type impurity concentration than the second silicon carbide layer and having a film thickness D1; a step of measuring a second film thickness D3 of the second silicon carbide layer and the film thickness D1 of the fourth silicon carbide layer in a direction from the first silicon carbide layer to the fourth silicon carbide layer after the fourth silicon carbide layer is formed; and a step of forming a trench having a predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer.

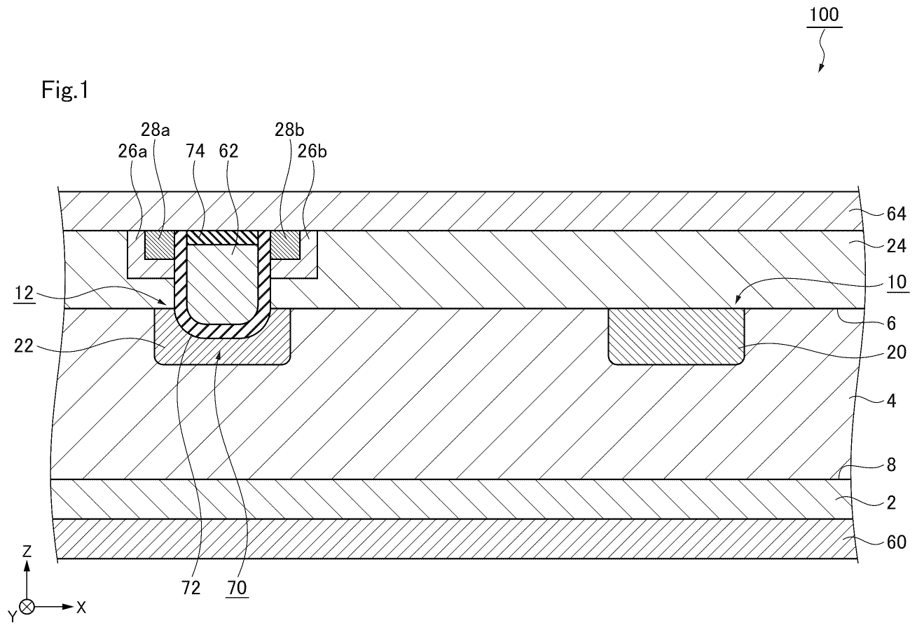

FIG. 1 is a schematic cross-sectional view of a semiconductor device 100 according to the present embodiment.

The semiconductor device 100 includes a first electrode 60, a silicon carbide substrate 2, a first silicon carbide layer 4, a second silicon carbide layer 20, a third silicon carbide layer 22, a fourth silicon carbide layer 24, a fifth silicon carbide layer 26, a sixth silicon carbide layer 28, a trench 70, a first insulating film 72, a second insulating film 74, a second electrode 62, and a third electrode 64.

The semiconductor device 100 according to the present embodiment is a trench type MISFET (Metal Insulator Semiconductor Field Effect Transistor). In addition, a MOSFET (Metal Oxide Semiconductor Field Effect Transistor) is a type of MISFET.

Here, an X direction, a Y direction perpendicular to the X direction, and a Z direction perpendicular to the X direction and the Y direction are defined. The first electrode 6, the silicon carbide substrate 2, the first silicon carbide layer 4, the fourth silicon carbide layer 24, and the third electrode 64 are provided in parallel in the XY plane. The Z direction is parallel to a direction in which the first electrode 60, the silicon carbide substrate 2, the first silicon carbide layer 4, the fourth silicon carbide layer 24, and the third electrode 64 are stacked. The Z direction is parallel to a direction from the first electrode 60 to the third electrode 64.

The n⁺-type silicon carbide substrate 2 contains n-type impurities of, for example, 1×10¹⁸ atoms/cm³ or more and 1×10¹⁹ atoms/cm³ or less. Here, the n-type impurity is, for example, N (nitrogen). However, the n-type impurity may be, for example, P (phosphorus). In addition, the n-type impurity may be, for example, both N (nitrogen) and P (phosphorus). The silicon carbide substrate 2 is, for example, a hexagonal SiC substrate (n⁺ substrate) containing N (nitrogen) as an n-type impurity. The silicon carbide substrate 2 is a substrate that functions as, for example, a drain of the MISFET.

The n⁻-type first silicon carbide layer 4 is provided on the silicon carbide substrate 2. The first silicon carbide layer 4 contains n-type impurities of, for example, 1×10¹⁵ atoms/cm³ or more and 5×10¹⁶ atoms/cm³ or less. The film thickness of the first silicon carbide layer 4 is, for example, 4 μm or more and 50 μm or less. The first silicon carbide layer 4 is, for example, a silicon carbide layer formed on the silicon carbide substrate 2 by an epitaxial growth method using a CVD method (Chemical Vapor Deposition method). The first silicon carbide layer 4 is a layer that functions as, for example, a drift layer of the MISFET.

The first silicon carbide layer 4 has a first surface 6 and a second surface 8. The second surface 8 is provided on a side opposite to the first surface 6. The second surface 8 is in contact with the silicon carbide substrate 2, for example. The first surface 6 is an example of an upper surface.

The n-type second silicon carbide layer 20 is provided in a first region 10 of the first surface 6. The n-type impurity concentration of the second silicon carbide layer 20 is different from the n-type impurity concentration of the first silicon carbide layer 4. However, when the second silicon carbide layer 20 is used as a current diffusion layer of a MOSFET, the n-type impurity concentration of the second silicon carbide layer 20 is preferably higher than the n-type impurity concentration of the first silicon carbide layer 4. The following explanation will be given on the assumption that the n-type impurity concentration of the second silicon carbide layer 20 is higher than the n-type impurity concentration of the first silicon carbide layer 4. The second silicon carbide layer 20 contains n-type impurities of, for example, 5×10¹⁶ atoms/cm³ or more and 5×10¹⁷ atoms/cm³ or less. The film thickness of the second silicon carbide layer 20 is, for example, 0.2 μm or more and 1.0 μm or less. The second silicon carbide layer 20 is a base doped layer for C-V measurement used for C-V measurement of the impurity concentration, which will be described later. The second silicon carbide layer 20 is formed by, for example, ion implantation of n-type impurities into the first region 10 using a patterned hard mask or the like (not shown). As a hard mask herein, for example, a silicon oxide film or a silicon nitride film is preferably used.

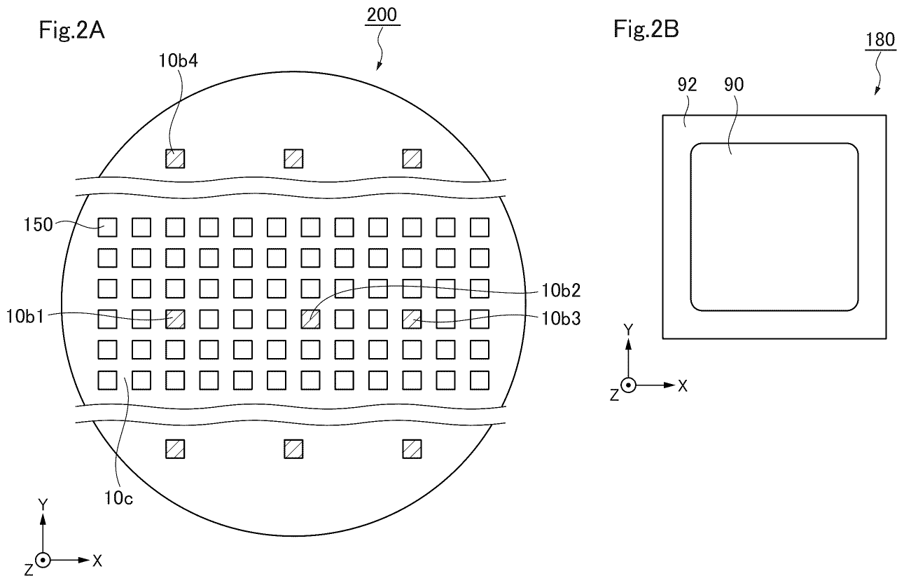

FIGS. 2A and 2B are schematic diagrams showing an example of a location where the first region 10 is arranged. FIG. 2A is a schematic top view of a wafer 200 on which the semiconductor device 100 according to the present embodiment is manufactured. The semiconductor device 100 is provided on a semiconductor chip 150. The semiconductor chip 150 is obtained by dicing the wafer 200.

A TEG (Test Element Group) region (TEG chip) 10b is an example of a region where the first region 10 is arranged. A TEG region 10b4 is provided at the edge of the wafer surface of the wafer 200. TEG regions 10b1, 10b2, and 10b3 are provided in portions of the wafer surface of the wafer 200 closer to the center than the TEG region 10b4. The TEG regions are regions where test chips formed on the wafer 200 are provided to evaluate semiconductor processes or semiconductor devices. In addition, the size of the TEG region 10b may be appropriately changed in accordance with the width of a C-V measurement probe R described later.

A dicing region (scribe lane) 10c is another example of the region where the first region 10 is arranged. The dicing region 10c is provided between the semiconductor chips 150. The dicing region 10c is a region that is cut by a dicing blade or the like during dicing. In addition, the size of the dicing region (scribe lane) 10c may be appropriately changed in accordance with the width of the C-V measurement probe R described later.

FIG. 2B is a diagram showing another example of the region where the first region 10 is arranged. Here, FIG. 2B shows a semiconductor chip 180 as an example. FIG. 2B is a schematic top view of the semiconductor chip 180. An outer peripheral region 92 is provided around a device region (active region) 90. The outer peripheral region 92 is another example of the region where the first region 10 is arranged. In addition, the size of the outer peripheral region 92 may be appropriately changed in accordance with the width of the C-V measurement probe R described later.

In addition, the location where the first region 10 is arranged is not limited to the above location.

The p-type third silicon carbide layer 22 is provided in a second region 12 of the first surface 6. The third silicon carbide layer 22 is a layer provided at a location where the bottom of the trench 70 is to be provided, in order to reduce the electric field at the bottom of the trench 70 described later. The third silicon carbide layer 22 contains p-type impurities of, for example, 5×10¹⁶ atoms/cm³ or more and 5×10¹⁷ atoms/cm³ or less. The film thickness of the third silicon carbide layer 22 is, for example, 0.2 μm or more and 1.0 μm or less. The p-type impurity is, for example, Al (aluminum). The third silicon carbide layer 22 is formed by, for example, ion implantation into the second region 12 using a patterned hard mask or the like (not shown). In addition, in FIG. 1, the length of the first region 10 in the X direction and the length of the second region 12 in the X direction are illustrated as being almost the same. However, the length of the first region 10 in the X direction may be appropriately changed in accordance with the width of the C-V measurement probe R described later.

The n⁻-type fourth silicon carbide layer 24 is provided on the first silicon carbide layer 4, the second silicon carbide layer 20, and the third silicon carbide layer 22. The fourth silicon carbide layer 24 is a layer formed on the first silicon carbide layer 4, the second silicon carbide layer 20, and the third silicon carbide layer 22 after the second silicon carbide layer 20 and the third silicon carbide layer 22 are formed. The fourth silicon carbide layer 24 is a layer that functions as, for example, a drift layer of the MISFET. The fourth silicon carbide layer 24 contains n-type impurities of, for example, 1×10¹⁵ atoms/cm³ or more and 5×10¹⁶ atoms/cm³ or less. The n-type impurity concentration of the fourth silicon carbide layer 24 is lower than the n-type impurity concentration of the second silicon carbide layer 20. The film thickness of the fourth silicon carbide layer 24 is, for example, 0.5 μm or more and 2 μm or less.

The p-type fifth silicon carbide layer 26 is provided on the fourth silicon carbide layer 24. The fifth silicon carbide layer 26 functions as a base of the MISFET. FIG. 1 shows a fifth silicon carbide layer 26a and a fifth silicon carbide layer 26b.

The n-type sixth silicon carbide layer 28 is provided on the fifth silicon carbide layer 26. The sixth silicon carbide layer 28 functions as a contact layer of the MISFET. FIG. 1 shows a sixth silicon carbide layer 28a and a sixth silicon carbide layer 28b.

The trench 70 extends from the fourth silicon carbide layer 24 to the third silicon carbide layer 22. The bottom of the trench 70 is provided in the third silicon carbide layer 22.

The first insulating film 72 is provided on the inner wall of the trench 70. The first insulating film 72 is a gate insulating film of the MOSFET. The first insulating film 72 contains an insulating material such as silicon oxide.

The second electrode 62 is provided in the trench 70 so as to face the fifth silicon carbide layer 26 with the first insulating film 72 interposed therebetween. The second electrode 62 is a gate electrode of the MISFET. The second electrode 62 contains, for example, a conductive material such as conductive polysilicon containing impurities.

The second insulating film 74 is provided on the second electrode 62. The second insulating film 74 contains an insulating material such as silicon oxide.

The first electrode 60 is provided below the silicon carbide substrate 2. The first electrode 60 is in contact with the silicon carbide substrate 2. The first electrode 60 contains, for example, a metal or a metal semiconductor compound. The first electrode 60 contains, for example, NiSi (nickel silicide), Ti (titanium), Ni (nickel), Ag (silver), or Au (gold). The first electrode 60 is a drain electrode of the MISFET.

The third electrode 64 is provided on the fourth silicon carbide layer 24, the fifth silicon carbide layer 26, the sixth silicon carbide layer 28, and the second insulating film 74. The third electrode 64 is in contact with, for example, the fourth silicon carbide layer 24, the fifth silicon carbide layer 26, the sixth silicon carbide layer 28, and the second insulating film 74. The third electrode 64 has, for example, a stacked structure of Ti (titanium) and Al (aluminum). In addition, the third electrode 64 may contain metal silicide, such as NiSi, in portions in contact with the fourth silicon carbide layer 24, the fifth silicon carbide layer 26, and the sixth silicon carbide layer 28.

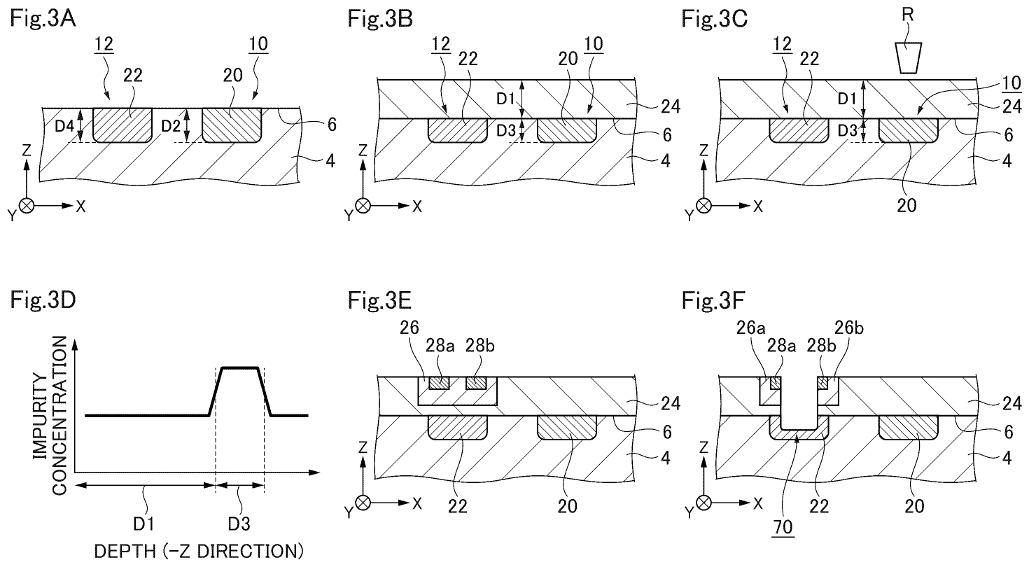

FIGS. 3A to 3F are schematic cross-sectional views showing steps of manufacturing the semiconductor device 100 according to the present embodiment.

First, the n⁻-type first silicon carbide layer 4 is formed on the silicon carbide substrate 2 (not shown in FIG. 3A) by an epitaxial growth method using a CVD method.

Then, the n-type second silicon carbide layer 20 is formed in the first region 10 of the first surface 6 of the first silicon carbide layer 4 by, for example, ion implantation using a patterned hard mask or the like (not shown). Here, the film thickness of the second silicon carbide layer 20 in the depth direction (−z direction) is D2 (first film thickness D2 of the second silicon carbide layer 20). The first film thickness D2 of the second silicon carbide layer 20 can be calculated, for example, by performing C-V measurement on the second silicon carbide layer 20 after performing an annealing treatment for activating impurities described later. In addition, in the case of SiC, impurity elements are less likely to diffuse than in the case of Si. For this reason, in the case of SiC, under typical activation annealing conditions for impurity elements, diffusion of the impurity elements hardly occurs. Therefore, when the second silicon carbide layer 20 is formed by ion implantation, there is almost no difference between the design value and the actual measured value of the film thickness. For this reason, this design value may be adopted as the first film thickness D2.

In addition, the p-type third silicon carbide layer 22 is formed in the second region 12 of the first surface 6 of the first silicon carbide layer 4 by ion implantation using a patterned hard mask or the like (not shown). The film thickness of the third silicon carbide layer 22 in the depth direction (−z direction) is D4. Here, the third silicon carbide layer 22 is formed by ion implantation. As described above, in the case of SiC, impurity elements are less likely to diffuse than in the case of Si. For this reason, in the case of SiC, under typical activation annealing conditions for impurity elements, diffusion of the impurity elements hardly occurs. Therefore, when the third silicon carbide layer 22 is formed by ion implantation, there is almost no difference between the design value and the actual measured value of the film thickness. For this reason, the design value of the film thickness of the third silicon carbide layer 22 can be adopted as the film thickness D4 (FIG. 3A).

Then, the n⁻-type fourth silicon carbide layer 24 is formed on the first silicon carbide layer 4, the second silicon carbide layer 20, and the third silicon carbide layer 22 by an epitaxial growth method using a CVD method.

The formation of the fourth silicon carbide layer 24 will be described. The silicon carbide substrate 2, the first silicon carbide layer 4, the second silicon carbide layer 20, and the third silicon carbide layer 22 are put into an epitaxial growth furnace (not shown). Then, by heating these to a temperature of, for example, 1500° C. or more and 1700° C. or less in an H₂ (hydrogen) gas atmosphere, the first surface 6 is etched with H₂ to be cleaned. This etching reduces the film thickness of the second silicon carbide layer 20 from D2 to D3 (second film thickness D3 of the second silicon carbide layer 20). The difference between D2 and D3 is, for example, about 0.01 μm or more and 0.2 μm. However, the difference between D2 and D3 is not limited to this.

In addition, the film thickness of the third silicon carbide layer 22 is also reduced from D4 by the above etching.

Then, an Si (silicon)-based gas and a C (carbon)-based gas, which are SiC source gases, and an n-type impurity gas are put into the epitaxial growth furnace together with the H₂ (hydrogen) gas. Here, the Si (silicon)-based gas is, for example, an SiH₄ (monosilane) gas. In addition, the C (carbon)-based gas is, for example, a C₃H₈ (propane) gas. In addition, the n-type impurity gas is, for example, an N₂ (nitrogen) gas. Then, for example, the fourth silicon carbide layer 24 is formed by holding the gases at a temperature of 1500° C. or more and 1700° C. or less. Here, the film thickness of the fourth silicon carbide layer 24 in the depth direction (z direction) is D1.

Here, the cleaning of the first surface 6 by H₂ etching and the formation of fourth silicon carbide layer 24 are generally performed consecutively in the same epitaxial growth furnace.

Then, the C-V measurement probe R is moved onto the fourth silicon carbide layer 24 on the second silicon carbide layer 20. Then, C-V measurement is performed (FIG. 3C). Here, the C-V measurement probe R used for the C-V measurement may be of either a contact type or a non-contact type. As a non-contact type C-V measurement probe, for example, a CnCV230 device manufactured by Semilab SDI can be preferably used. In addition, in FIGS. 3A to 3C, 3E, and 3F, the length of the first region 10 in the X direction is illustrated as being almost the same as the length of the second region 12 in the X direction. However, the length of the first region 10 in the X direction may be appropriately changed in accordance with the width of the C-V measurement probe R.

FIG. 3D shows the concentration distribution (profile) of the impurity concentration in the depth direction (−z direction) obtained from the C-V measurement. Using this concentration distribution, the film thickness D1 of the fourth silicon carbide layer 24 and the second film thickness D3 of the second silicon carbide layer 20 can be calculated. Here, for example, the n-type impurity concentration of the second silicon carbide layer 20 is higher than the n-type impurity concentration of the first silicon carbide layer 4 and the n-type impurity concentration of the fourth silicon carbide layer 24. Therefore, a portion at a depth where the n-type impurity concentration is higher can be set as the second film thickness D3 of the second silicon carbide layer 20.

The amount by which the second silicon carbide layer 20 is etched is ((the first film thickness D2 of the second silicon carbide layer 20)−(the second film thickness D3 of the second silicon carbide layer 20)). Therefore, the amount by which the first surface 6 and the third silicon carbide layer 22 are etched can be set as ((the first film thickness D2 of the second silicon carbide layer 20)−(the second film thickness D3 of the second silicon carbide layer 20)).

Then, the fifth silicon carbide layer 26 is formed on the fourth silicon carbide layer 24 by ion implantation using a hard mask or the like (not shown). In addition, the sixth silicon carbide layer 28 is formed on the fifth silicon carbide layer 26 by ion implantation using a hard mask or the like (not shown) (FIG. 3E).

In addition, here, for example, a p-type contact layer (not shown) may be formed. In addition, an annealing treatment for activating impurities may be performed.

Then, using, for example, an RIE (Reactive Ion Etching) method, the trench 70 that has a predetermined depth and that penetrates the fourth silicon carbide layer 24 and reaches the third silicon carbide layer 22 is formed based on the film thickness D1 of the fourth silicon carbide layer 24, the first film thickness D2 of the second silicon carbide layer 20, the second film thickness D3 of the second silicon carbide layer 20, and the film thickness D4 of the third silicon carbide layer.

Here, assuming that the film thickness of the third silicon carbide layer 22 is D4, the predetermined depth of the trench 70 is preferably determined based on (the film thickness D1 of the fourth silicon carbide layer)+((the film thickness D4 of the third silicon carbide layer)−((the first film thickness D2 of the second silicon carbide layer)−(the second film thickness D3 of the second silicon carbide layer)))/2.

Then, the first insulating film 72, the second electrode 62, the second insulating film 74, the first electrode 60, and the third electrode 64 are formed as appropriate, thereby obtaining the semiconductor device 100 according to the present embodiment.

Next, the function and effect of the present embodiment will be described.

It is conceivable to provide the p-type third silicon carbide layer 22 at a place where the bottom of the trench 70 is located, in order to reduce the electric field at the bottom of the trench 70, in a trench type MISFET.

However, before forming the fourth silicon carbide layer 24 after forming the third silicon carbide layer 22, the first silicon carbide layer 4, the second silicon carbide layer 20, and the third silicon carbide layer 22 are etched by the H₂ gas introduced into the epitaxial growth furnace. The amount of etching by this H₂ gas and the film thickness of the fourth silicon carbide layer 24 vary depending on the state of the epitaxial growth furnace, the degree of warpage of the substrate, and the like.

For this reason, when forming the trench 70, there have been cases where the bottom of the trench 70 is not provided within the third silicon carbide layer 22. As a result, there has been a problem in that the yield of semiconductor devices decreases.

Therefore, the method for manufacturing a semiconductor device according to the present embodiment includes: a step of forming, in a first region of an upper surface of a first-conductivity-type first silicon carbide layer, a second silicon carbide layer having a first-conductivity-type impurity concentration different from that of the first silicon carbide layer and having a first film thickness D2; a step of forming a second-conductivity-type third silicon carbide layer having a film thickness D4 in a second region of the upper surface; a step of forming, on the first silicon carbide layer, a fourth silicon carbide layer having a lower first-conductivity-type impurity concentration than the second silicon carbide layer and having a film thickness D1; a step of measuring a second film thickness D3 of the second silicon carbide layer and the film thickness D1 of the fourth silicon carbide layer in a direction from the first silicon carbide layer to the fourth silicon carbide layer after the fourth silicon carbide layer is formed; and a step of forming a trench having a predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer.

The amount of etching by the H₂ gas can be calculated in the semiconductor device manufacturing step by using the first film thickness D2 and the second film thickness D3 of the second silicon carbide layer. Therefore, the calculated amount of etching by the H₂ gas can be reflected in the depth of the trench 70 to be formed. As a result, it is possible to provide a method for manufacturing a semiconductor device with an improved yield.

When the depth of the trench 70 is determined based on (the film thickness D1 of the fourth silicon carbide layer)+((the film thickness D4 of the third silicon carbide layer)−((the first film thickness D2 of the second silicon carbide layer)−(the second film thickness D3 of the second silicon carbide layer)))/2, the depth of the trench 70 is controlled so that the bottom of the trench 70 is located at the center of the third silicon carbide layer in the Z direction. Therefore, it is possible to provide a method for manufacturing a semiconductor device with a further improved yield.

The first region 10 can be provided in the TEG region, the scribe lane, and the outer peripheral region. This is because the effect on the device characteristics can be suppressed.

According to the present embodiment, it is possible to provide a semiconductor device with an improved yield and a method for manufacturing the same.

### Second Embodiment

The present embodiment is different from the first embodiment in that the first region is provided around the second region on the first surface. Here, the description of the content overlapping the first embodiment will be omitted.

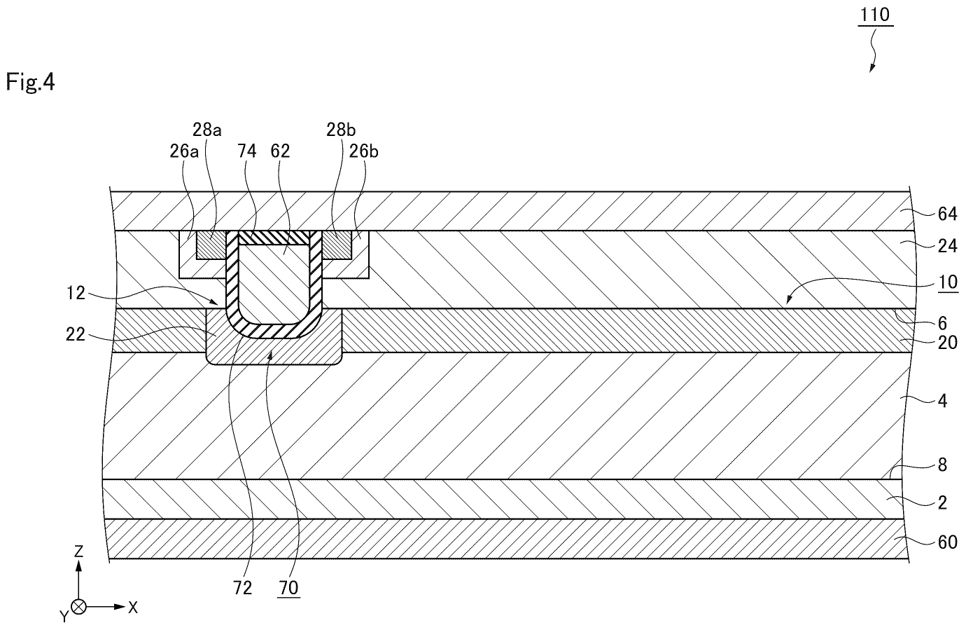

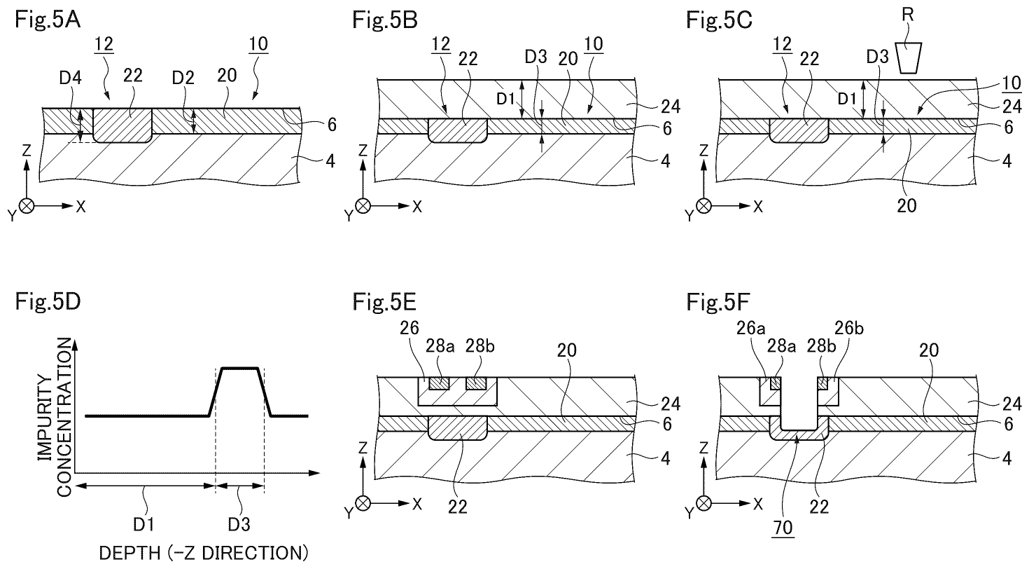

FIG. 4 is a schematic cross-sectional view of a semiconductor device 110 according to the present embodiment. FIGS. 5A to 5F are schematic cross-sectional views showing steps of manufacturing the semiconductor device according to the present embodiment.

A first region 10 is provided around a second region 12 so as to surround the second region 12. Therefore, a second silicon carbide layer 20 is provided around a third silicon carbide layer 22.

In other words, in the semiconductor device 110 according to the present embodiment, it can be said that the first region 10 is also provided in the device region 90 (FIG. 2B). Therefore, in the semiconductor device 110 according to the present embodiment, it can be said that the second silicon carbide layer 20 is also provided in the device region 90.

The second silicon carbide layer 20 functions as a current diffusion layer. Therefore, the resistance component or the on-resistance of the semiconductor device can be further reduced.

In addition, the second silicon carbide layer 20 according to the present embodiment is formed, for example, on the first silicon carbide layer 4 by an epitaxial growth method using a CVD method, similarly to the first silicon carbide layer 4. As a result, it is possible to reduce the number of ion implantation steps by one.

According to the present embodiment, it is possible to provide a semiconductor device with an improved yield and a method for manufacturing the same.

### Third Embodiment

The present embodiment is different from the first and second embodiments in that the concentration distribution of the first-conductivity-type impurities in the second silicon carbide layer in a direction from the first silicon carbide layer to the fourth silicon carbide layer has a plurality of peaks.

A semiconductor device according to the present embodiment includes: a first electrode; a first-conductivity-type silicon carbide substrate provided on the first electrode; a first-conductivity-type first silicon carbide layer provided on the silicon carbide substrate; a second silicon carbide layer provided in a first region of an upper surface of the first silicon carbide layer and having a higher first-conductivity-type impurity concentration than the first silicon carbide layer, a concentration distribution of first-conductivity-type impurities in a direction from the first electrode to the first silicon carbide layer having a plurality of peaks; a second-conductivity-type third silicon carbide layer provided in a second region of the upper surface; a fourth silicon carbide layer provided on the first silicon carbide layer and having a lower first-conductivity-type impurity concentration than the second silicon carbide layer; a second-conductivity-type fifth silicon carbide layer provided on the fourth silicon carbide layer; a first-conductivity-type sixth silicon carbide layer provided on the fifth silicon carbide layer; a trench penetrating the fourth silicon carbide layer to reach the third silicon carbide layer; a first insulating film provided in the trench; a second electrode provided in the trench so as to face the fifth silicon carbide layer with the first insulating film interposed therebetween; a second insulating film provided on the second electrode; and a third electrode provided on the sixth silicon carbide layer and the second insulating film.

Here, the description of the content overlapping the first and second embodiments will be omitted.

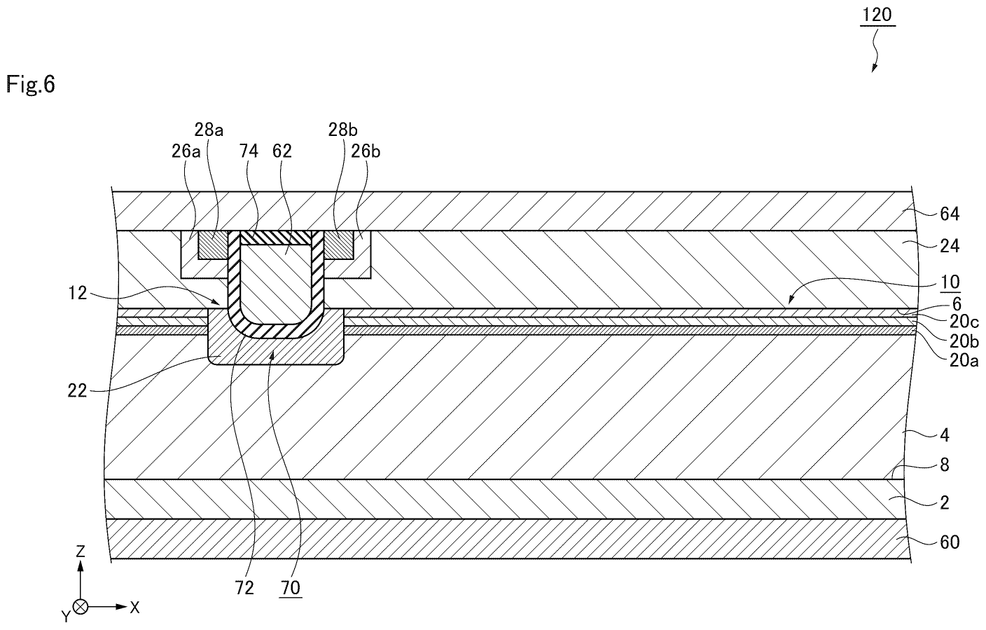

FIG. 6 is a schematic cross-sectional view of a semiconductor device 120 according to the present embodiment. In FIG. 6, a second silicon carbide layer 20 is provided around a third silicon carbide layer 22, for example, similarly to the semiconductor device 110 according to the second embodiment. Then, the second silicon carbide layer 20 has an eighth silicon carbide layer 20a having a higher n-type impurity concentration than the first silicon carbide layer 4, a ninth silicon carbide layer 20b provided on the eighth silicon carbide layer 20a and having a lower n-type impurity concentration than the eighth silicon carbide layer 20a, and a tenth silicon carbide layer 20c provided on the ninth silicon carbide layer 20b and having a higher n-type impurity concentration than the ninth silicon carbide layer 20b and the fourth silicon carbide layer 24. For example, the eighth silicon carbide layer 20a, the ninth silicon carbide layer 20b, and the tenth silicon carbide layer 20c each have a film thickness of about 0.1 μm. The eighth silicon carbide layer 20a and the tenth silicon carbide layer 20c have an n-type impurity concentration of, for example, about 1×10¹⁷ atoms/cm³. In addition, the ninth silicon carbide layer 20b has an n-type impurity concentration of, for example, about 5×10¹⁶ atoms/cm³.

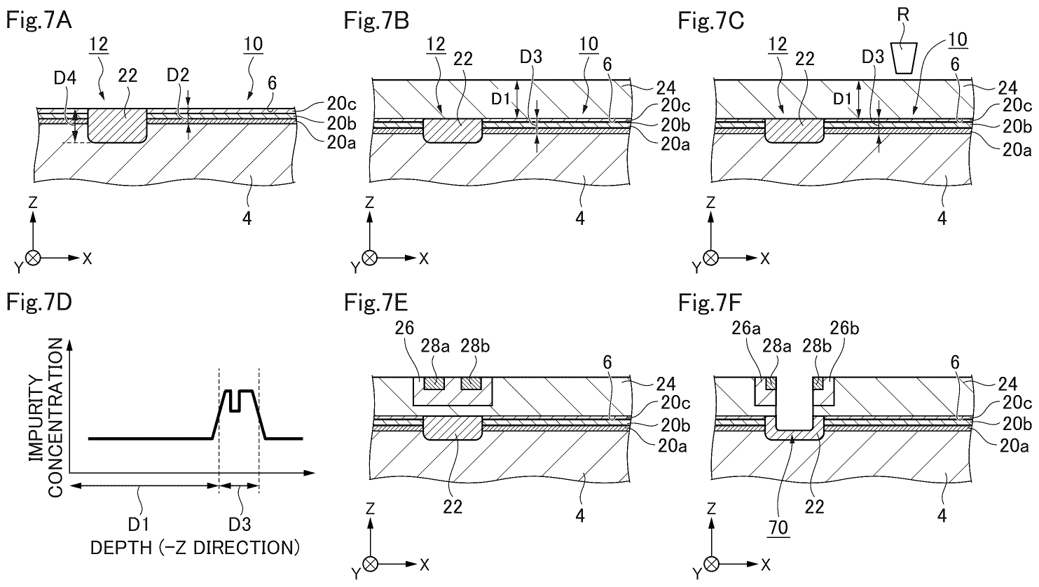

FIGS. 7A to 7F are schematic cross-sectional views showing steps of manufacturing the semiconductor device according to the present embodiment. In FIG. 7D, the concentration distribution (profile) of the impurity concentration in the depth direction (−z direction) obtained from the C-V measurement has a plurality of peaks corresponding to the n-type impurity concentrations of the eighth silicon carbide layer 20a and the tenth silicon carbide layer 20c.

In the present embodiment, the film thickness of second silicon carbide layer 20 can be estimated based on the impurity concentration distribution shown in FIG. 7D. Specifically, the eighth silicon carbide layer 20a, the ninth silicon carbide layer 20b, and the tenth silicon carbide layer 20c each have a film thickness of about 0.1 μm, and the amount of etching by the H₂ gas can be visually known through FIG. 7D. For example, since it can be seen in FIG. 7D that about half of the tenth silicon carbide layer 20c is etched, the amount of etching can be estimated to be about 0.05 μm. In this manner, it is possible to simplify the step of calculating the film thickness of the second silicon carbide layer 20 before the fourth silicon carbide layer 24 is formed.

According to the present embodiment, it is possible to provide a semiconductor device with an improved yield and a method for manufacturing the same.

### Fourth Embodiment

A semiconductor device according to the present embodiment is different from the semiconductor devices according to the first to third embodiments in that a seventh silicon carbide layer 30 having a higher first-conductivity-type impurity concentration than the first silicon carbide layer 4 and the fourth silicon carbide layer 24 is further provided between the first silicon carbide layer 4 and the fourth silicon carbide layer 24.

A method for manufacturing a semiconductor device according to the present embodiment is different from the methods for manufacturing a semiconductor device according to the first to third embodiments in that the method for manufacturing a semiconductor device according to the present embodiment further includes a step of forming a seventh silicon carbide layer having a higher first-conductivity-type impurity concentration than the first silicon carbide layer and the fourth silicon carbide layer on the third silicon carbide layer before forming the fourth silicon carbide layer after forming the third silicon carbide layer.

Here, the description of the content overlapping the first to third embodiments will be omitted.

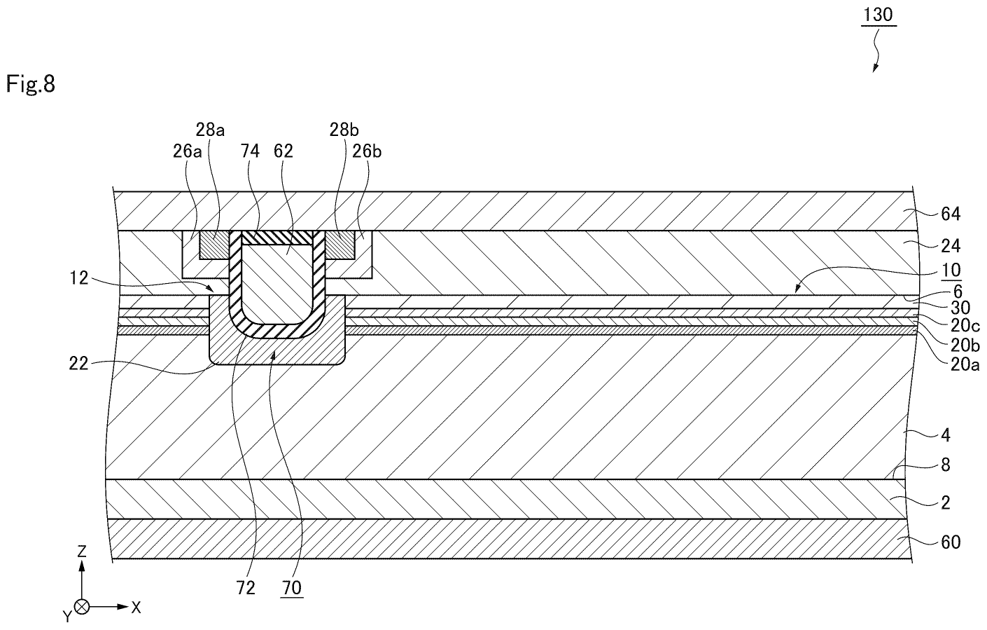

FIG. 8 is a schematic cross-sectional view of a semiconductor device 130 according to the present embodiment.

The seventh silicon carbide layer 30 functions as a current diffusion layer. Therefore, the resistance component or the on-resistance of the semiconductor device can be further reduced.

According to the present embodiment, it is possible to provide a semiconductor device with an improved yield and a method for manufacturing the same.

While several embodiments and practical examples of the invention have been described, these embodiments and practical examples are presented as examples and are not intended to limit the scope of the invention. These novel embodiments can be implemented in various other forms, and various omissions, replacements, and modifications can be made without departing from the spirit of the invention. These embodiments or their modifications are included in the scope or spirit of the invention, and are included in the inventions described in the claims and their equivalents.

In addition, the embodiments described above can be summarized as the following technical proposals.

### Technical Proposal 1

A method for manufacturing a semiconductor device, including:
a step of forming, in a first region of an upper surface of a first-conductivity-type first silicon carbide layer, a second silicon carbide layer having a first-conductivity-type impurity concentration different from that of the first silicon carbide layer and having a first film thickness D2;
a step of forming a second-conductivity-type third silicon carbide layer having a film thickness D4 in a second region of the upper surface;
a step of forming, on the first silicon carbide layer, a fourth silicon carbide layer having a lower first-conductivity-type impurity concentration than the second silicon carbide layer and having a film thickness D1;
a step of measuring a second film thickness D3 of the second silicon carbide layer and the film thickness D1 of the fourth silicon carbide layer in a direction from the first silicon carbide layer to the fourth silicon carbide layer after the fourth silicon carbide layer is formed; and
a step of forming a trench having a predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer.

### Technical Proposal 2

The method for manufacturing a semiconductor device according to Technical Proposal 1,
wherein the trench having the predetermined depth is formed based on (the film thickness D1 of the fourth silicon carbide layer)+((the film thickness D4 of the third silicon carbide layer)−((the first film thickness D2 of the second silicon carbide layer)−(the second film thickness D3 of the second silicon carbide layer)))/2.

### Technical Proposal 3

The method for manufacturing a semiconductor device according to Technical Proposal 1 or 2, further including:
before the step of forming the trench having the predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer, a step of forming a second-conductivity-type fifth silicon carbide layer on the fourth silicon carbide layer on the third silicon carbide layer and a step of forming a first-conductivity-type sixth silicon carbide layer on the fifth silicon carbide layer, and
after the step of forming the trench having the predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer, a step of forming a first insulating film in the trench, a step of forming a second electrode provided in the trench so as to face the fifth silicon carbide layer with the first insulating film interposed therebetween, a step of forming a second insulating film on the second electrode, a step of forming a first electrode below the first silicon carbide layer, and a step of forming a third electrode on the sixth silicon carbide layer.

### Technical Proposal 4

The method for manufacturing a semiconductor device according to any one of Technical Proposals 1 to 3,
wherein, on the upper surface, the first region is provided around the second region.

### Technical Proposal 5

The method for manufacturing a semiconductor device according to any one of Technical Proposals 1 to 4,
wherein the first region is provided in a TEG region of the semiconductor device.

### Technical Proposal 6

The method for manufacturing a semiconductor device according to any one of Technical Proposals 1 to 4,
wherein the first region is provided in a scribe lane of the semiconductor device.

### Technical Proposal 7

The method for manufacturing a semiconductor device according to Technical Proposal 1,
wherein the first region is provided in an outer peripheral region of the semiconductor device.

### Technical Proposal 8

The method for manufacturing a semiconductor device according to any one of Technical Proposals 1 to 7,
wherein a concentration distribution of first-conductivity-type impurities in the second silicon carbide layer in a direction from the first silicon carbide layer to the fourth silicon carbide layer has a plurality of peaks.

### Technical Proposal 9

The method for manufacturing a semiconductor device according to any one of Technical Proposals 1 to 7, further including:
before forming the fourth silicon carbide layer after forming the third silicon carbide layer, a step of forming, on the third silicon carbide layer, a seventh silicon carbide layer having a higher first-conductivity-type impurity concentration than the first silicon carbide layer and the fourth silicon carbide layer.

### Technical Proposal 10

A semiconductor device, including:
a first electrode;
a first-conductivity-type silicon carbide substrate provided on the first electrode;
a first-conductivity-type first silicon carbide layer provided on the silicon carbide substrate;
a second silicon carbide layer provided in a first region of an upper surface of the first silicon carbide layer and having a higher first-conductivity-type impurity concentration than the first silicon carbide layer;
a second-conductivity-type third silicon carbide layer provided in a second region of the upper surface;
a fourth silicon carbide layer provided on the first silicon carbide layer and having a lower first-conductivity-type impurity concentration than the second silicon carbide layer;
a second-conductivity-type fifth silicon carbide layer provided on the fourth silicon carbide layer;
a first-conductivity-type sixth silicon carbide layer provided on the fifth silicon carbide layer;
a trench penetrating the fourth silicon carbide layer to reach the third silicon carbide layer;
a first insulating film provided in the trench;
a second electrode provided in the trench so as to face the fifth silicon carbide layer with the first insulating film interposed therebetween;
a second insulating film provided on the second electrode; and
a third electrode provided on the sixth silicon carbide layer and the second insulating film.

While certain embodiments have been described, these embodiments have been presented by way of example only, and are not intended to limit the scope of the inventions. Indeed, SEMICONDUCTOR DEVICE AND METHOD FOR MANUFACTURING THE SAME described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
a step of forming, in a first region of an upper surface of a first-conductivity-type first silicon carbide layer, a second silicon carbide layer having a first-conductivity-type impurity concentration different from that of the first silicon carbide layer and having a first film thickness D2;
a step of forming a second-conductivity-type third silicon carbide layer having a film thickness D4 in a second region of the upper surface;
a step of forming, on the first silicon carbide layer, a fourth silicon carbide layer having a lower first-conductivity-type impurity concentration than the second silicon carbide layer and having a film thickness D1;
a step of measuring a second film thickness D3 of the second silicon carbide layer and the film thickness D1 of the fourth silicon carbide layer in a direction from the first silicon carbide layer to the fourth silicon carbide layer after the fourth silicon carbide layer is formed; and
a step of forming a trench having a predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer.

2. The method for manufacturing a semiconductor device according to claim 1,
wherein the trench having the predetermined depth is formed based on (the film thickness D1 of the fourth silicon carbide layer)+((the film thickness D4 of the third silicon carbide layer)−((the first film thickness D2 of the second silicon carbide layer)−(the second film thickness D3 of the second silicon carbide layer)))/2.

3. The method for manufacturing a semiconductor device according to claim 1, further comprising:
before the step of forming the trench having the predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer, a step of forming a second-conductivity-type fifth silicon carbide layer on the fourth silicon carbide layer on the third silicon carbide layer and a step of forming a first-conductivity-type sixth silicon carbide layer on the fifth silicon carbide layer, and
after the step of forming the trench having the predetermined depth and penetrating the fourth silicon carbide layer to reach the third silicon carbide layer based on the film thickness D1 of the fourth silicon carbide layer, the first film thickness D2 and the second film thickness D3 of the second silicon carbide layer, and the film thickness D4 of the third silicon carbide layer, a step of forming a first insulating film in the trench, a step of forming a second electrode provided in the trench so as to face the fifth silicon carbide layer with the first insulating film interposed therebetween, a step of forming a second insulating film on the second electrode, a step of forming a first electrode below the first silicon carbide layer, and a step of forming a third electrode on the sixth silicon carbide layer.

4. The method for manufacturing a semiconductor device according to claim 1,
wherein, on the upper surface, the first region is provided around the second region.

5. The method for manufacturing a semiconductor device according to claim 1,
wherein the first region is provided in a TEG region of the semiconductor device.

6. The method for manufacturing a semiconductor device according to claim 1,
wherein the first region is provided in a scribe lane of the semiconductor device.

7. The method for manufacturing a semiconductor device according to claim 1,
wherein the first region is provided in an outer peripheral region of the semiconductor device.

8. The method for manufacturing a semiconductor device according to claim 1,
wherein a concentration distribution of first-conductivity-type impurities in the second silicon carbide layer in a direction from the first silicon carbide layer to the fourth silicon carbide layer has a plurality of peaks.

9. The method for manufacturing a semiconductor device according to claim 1, further comprising:
before forming the fourth silicon carbide layer after forming the third silicon carbide layer, a step of forming, on the third silicon carbide layer, a seventh silicon carbide layer having a higher first-conductivity-type impurity concentration than the first silicon carbide layer and the fourth silicon carbide layer.
